(19) United States
(12) Patent Application Publication
(10) Pub. No.: US 2024/0244357 A1
(43) Pub. Date: Jul. 18, 2024

(54) Metal Shell, Speaker Device and Vibrator Device

(71) Applicant: AAC Microtech (Changzhou) Co., Ltd., Changzhou (CN)

(72) Inventors: Qibo Li, Changzhou (CN); Jingwei Yu, Changzhou (CN); Zhongfeng Gao, Changzhou (CN); Siyuan Ni, Changzhou (CN)

(21) Appl. No.: 18/321,790

(22) Filed: May 23, 2023

Related U.S. Application Data
(63) Continuation of application No. PCT/CN2023/085271, filed on Mar. 30, 2023.

(30) Foreign Application Priority Data
Jan. 17, 2023 (CN) 202320154543.3

(51) Int. Cl. H04R 1/02

(52) U.S. Cl. CPC H04R 1/02

(57) ABSTRACT

Disclosed is a metal shell which can be molded without molding breakages from a metal plate and includes a bottom wall including a first edge and a second edge adjacent to the first edge, a first side wall, a second side wall, a first arc transition part connecting the first edge and the first side wall, a second arc transition part connecting the second edge and the second side wall, a third arc transition part connecting the two side walls, and a spherical transition part located at a junction position of the three arc transition parts and connecting the three arc transition parts. A radius of the third arc transition part is greater than a radius of the first arc transition part and a radius of the second arc transition part. A radius of the spherical transition part is equal to the radius of the third arc transition part.

### FIELD OF THE PRESENT DISCLOSURE

The present disclosure relates to device shells, in particular to a metal shell and a speaker device and a vibrator device using the metal shell.

### DESCRIPTION OF THE RELATED ART

A metal shell in the related art is usually molded from a metal plate to form a bottom wall and side walls. However, in the actual molding process, molding breakages of the metal shell often happen.

Thus, it is necessary to provide a novel metal shell to solve the problem.

### SUMMARY

An objective of the present disclosure is to overcome the above technical problem and provide a metal shell which can be molded without molding breakages from a metal plate.

In order to achieve the objective mentioned above, the present disclosure discloses a metal shell including a bottom wall including a first edge and a second edge adjacent to the first edge, a first side wall corresponding to the first edge, a second side wall corresponding to the second edge, a first arc transition part connecting the first edge and the first side wall, a second arc transition part connecting the second edge and the second side wall, a third arc transition part connecting the first side wall and the second side wall, and a spherical transition part located at a junction position of the first arc transition part, the second arc transition part and the third arc transition part and connecting the first arc transition part, the second arc transition part and the third arc transition part. A radius of the third arc transition part is greater than a radius of the first arc transition part. The radius of the third arc transition part is greater than a radius of the second arc transition part. A radius of the spherical transition part is equal to the radius of the third arc transition part.

As an improvement, the first side wall is perpendicular to the bottom wall. The second side wall is perpendicular to the bottom wall. The first side wall is perpendicular to the second side wall.

As an improvement, the radius of the first arc transition part is equal to the radius of the second arc transition part.

As an improvement, the radius of the first arc transition part and the radius of the second arc transition part are both 0.2 mm.

As an improvement, the radius of the third arc transition part is 0.5 mm to 1 mm.

The present disclosure also discloses a speaker device including the metal shell.

The present disclosure also discloses a vibrator device including the metal shell.

In the metal shell according to the present disclosure, the radius of the third arc transition part is greater than the radius of the first arc transition part. The radius of the third arc transition part is greater than the radius of the second arc transition part. The radius of the spherical transition part is equal to the radius of the third arc transition part. By redesigning the overall structure of the metal shell, the metal shell can be molded without molding breakages from a metal plate.

### BRIEF DESCRIPTION OF THE DRAWINGS

In order to more clearly illustrate the technical solutions in embodiments of the present disclosure, the accompanying drawings used in the description of the embodiments will be briefly introduced below. It is apparent that, the accompanying drawings in the following description are only some embodiments of the present disclosure, and other drawings can be obtained by those of ordinary skill in the art based on the accompanying drawings without creative efforts, wherein:

FIG. 1 is an isometric view of a metal shell in accordance with an exemplary embodiment of the present disclosure.

FIG. 2 is an isometric view of the metal shell in FIG. 1, from another aspect.

### DETAILED DESCRIPTION OF THE EMBODIMENTS

The technical solutions in embodiments of the present disclosure will be described clearly and completely below with reference to the accompanying drawings in the embodiments of the present disclosure. It is apparent that, the described embodiments are merely some of rather than all of the embodiments of the present disclosure. All other embodiments acquired by those of ordinary skill in the art without creative efforts based on the embodiments of the present disclosure shall fall within the protection scope of the present disclosure.

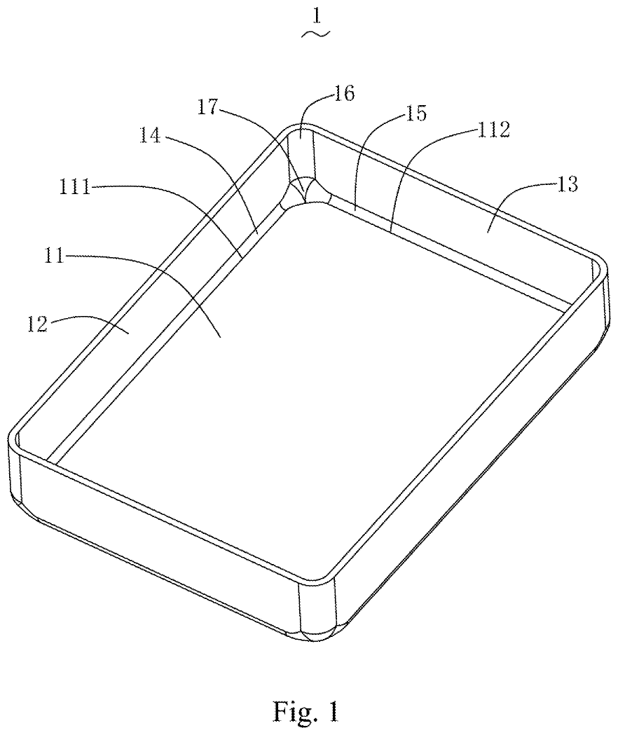

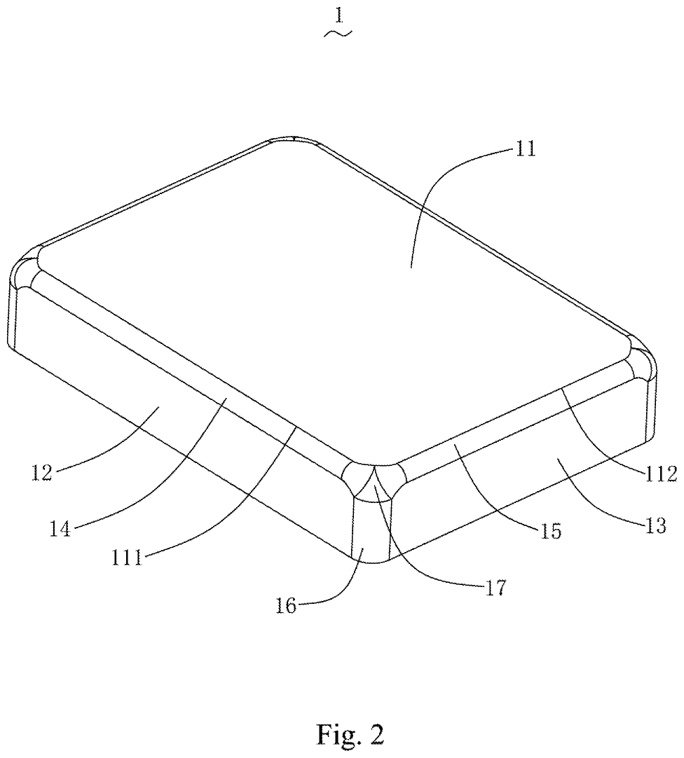

Referring to FIGS. 1-2, the present disclosure discloses a metal shell 1. The metal shell 1 includes a bottom wall 11 including a first edge 111 and a second edge 112 adjacent to the first edge 111, a first side wall 12 corresponding to the first edge 111, a second side wall 13 corresponding to the second edge 112, a first arc transition part 14 connecting the first edge 111 and the first side wall 12, a second arc transition part 15 connecting the second edge 112 and the second side wall 13, a third arc transition part 16 connecting the first side wall 12 and the second side wall 13, and a spherical transition part 17 located at a junction position of the first arc transition part 14, the second arc transition part 15 and the third arc transition part 16 and connecting the first arc transition part 14, the second arc transition part 15 and the third arc transition part 16.

A radius of the third arc transition part 16 is greater than a radius of the first arc transition part 14. The radius of the third arc transition part 16 is greater than a radius of the second arc transition part 15. A radius of the spherical transition part 17 is equal to the radius of the third arc transition part 16.

Optionally, the first side wall 12 is perpendicular to the bottom wall 11. The second side wall 13 is perpendicular to the bottom wall 11. The first side wall 12 is perpendicular to the second side wall 13.

Optionally, the radius of the first arc transition part 14 is equal to the radius of the second arc transition part 15.

In this embodiment, the radius of the first arc transition part 14 and the radius of the second arc transition part 15 are both 0.2 mm. The radius of the third arc transition part 16 is 0.5 mm to 1 mm.

The present disclosure also discloses a speaker device including the metal shell 1.

The present disclosure also discloses a vibrator device including the metal shell 1.

In the metal shell 1 according to the present disclosure, the radius of the third arc transition part 16 is greater than the radius of the first arc transition part 14. The radius of the third arc transition part 16 is greater than the radius of the second arc transition part 15. The radius of the spherical transition part 17 is equal to the radius of the third arc transition part 16. By redesigning the overall structure of the metal shell 1, the metal shell 1 can be molded without molding breakages from a metal plate.

The above are only embodiments of the present disclosure. It should be pointed out that those of ordinary skill in the art may also make improvements without departing from the ideas of the present disclosure, all of which fall within the protection scope of the present disclosure.

What is claimed is:

1. A metal shell, comprising:
a bottom wall, comprising a first edge and a second edge adjacent to the first edge;
a first side wall corresponding to the first edge;
a second side wall corresponding to the second edge;
a first arc transition part connecting the first edge and the first side wall;
a second arc transition part connecting the second edge and the second side wall;
a third arc transition part connecting the first side wall and the second side wall; and
a spherical transition part located at a junction position of the first arc transition part, the second arc transition part and the third arc transition part and connecting the first arc transition part, the second arc transition part and the third arc transition part, wherein
a radius of the third arc transition part is greater than a radius of the first arc transition part, the radius of the third arc transition part is greater than a radius of the second arc transition part, a radius of the spherical transition part is equal to the radius of the third arc transition part.

2. The metal shell as described in claim 1, wherein the first side wall is perpendicular to the bottom wall, the second side wall is perpendicular to the bottom wall, the first side wall is perpendicular to the second side wall.

3. The metal shell as described in claim 1, wherein the radius of the first arc transition part is equal to the radius of the second arc transition part.

4. The metal shell as described in claim 3, wherein the radius of the first arc transition part and the radius of the second arc transition part are both 0.2 mm.

5. The metal shell as described in claim 3, wherein the radius of the third arc transition part is 0.5 mm to 1 mm.

6. A speaker device, comprising the metal shell as described in claim 1.

7. A vibrator device, comprising the metal shell as described in claim 1.
